(19) United States
(12) Patent Application Publication
(10) Pub. No.: US 2009/0305148 A1
(43) Pub. Date: Dec. 10, 2009

(54) PATTERN DATA CREATING METHOD, PHOTOMASK FABRICATING METHOD, AND METHOD OF MANUFACTURING SEMICONDUCTOR DEVICE

(76) Inventor: Masafumi ASANO, Yokohama-Shi (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/472,040

(22) Filed: May 26, 2009

(30) Foreign Application Priority Data
Jun. 5, 2008 (JP) 2008-147978

(51) Int. Cl. G03F 1/00; G03F 7/20

(52) U.S. Cl. 430/5; 430/30

(57) ABSTRACT

A pattern data creating method according to an embodiment of the present invention creates data of a mask pattern to be arranged on a photomask. The method includes creating a test mask pattern by moving positions of plural edges in a given mask pattern according to a predetermined probability density distribution, the test mask pattern having dimension values which are different from dimension values of the given mask pattern, obtaining dimension values of a wafer pattern, which are measured by exposing a wafer with a test mask on which the test mask pattern is arranged, forming the wafer pattern on the wafer by the exposure, and measuring the dimension values of the wafer pattern on the wafer, obtaining a relationship between the dimension values of the wafer pattern and the dimension values of the test mask pattern, and creating, by using the relationship, the mask pattern having dimension values by which a wafer pattern having predetermined dimension values is formed.

### CROSS REFERENCE TO RELATED APPLICATION

This application is based upon and claims the benefit of priority from the prior Japanese Patent Application No. 2008-147978, filed on Jun. 5, 2008, the entire contents of which are incorporated herein by reference.

### BACKGROUND OF THE INVENTION

1. Field of the Invention

The present invention relates to a pattern data creating method, a photomask fabricating method, and a method of manufacturing a semiconductor device.

2. Background Art

Recently, due to a miniaturization of an integrated circuit pattern, an optical proximity effect (OPE) during an exposure becomes troublesome. One of problems with the OPE is that a pattern identical to a mask pattern is not formed on a wafer. Therefore, it is necessary that the mask pattern be corrected such that the same pattern as the target is formed on the wafer. The correction is referred to as optical proximity correction (OPC).

In determining a correction amount of the mask pattern, there is often adopted a method of creating various test patterns whose correction amounts are different one another, and obtaining an optimum correction amount by an experiment. In a case where the method is adopted, efficiency of the experiment and accuracy of the optimization depend on a manner of deciding the correction amounts of the test patterns. Therefore, there is a need for the method to improve the efficiency of the experiment and the accuracy of the optimization.

An example of a pattern data creating method using a neural network is disclosed in an article ““Neural Network based approach to resist modeling and OPC”, Franz Zach, Proc. of SPIE vol. 5377, pp. 670-679, 2004”.

### SUMMARY OF THE INVENTION

An aspect of the present invention is, for example, a pattern data creating method for creating data of a mask pattern to be arranged on a photomask, the method including creating a test mask pattern by moving positions of plural edges in a given mask pattern according to a predetermined probability density distribution, the test mask pattern having dimension values which are different from dimension values of the given mask pattern, obtaining dimension values of a wafer pattern, which are measured by exposing a wafer with a test mask on which the test mask pattern is arranged, forming the wafer pattern on the wafer by the exposure, and measuring the dimension values of the wafer pattern on the wafer, obtaining a relationship between the dimension values of the wafer pattern and the dimension values of the test mask pattern, and creating, by using the relationship, the mask pattern having dimension values by which a wafer pattern having predetermined dimension values is formed.

Another aspect of the present invention is, for example, a photomask fabricating method for fabricating a photomask by using data of a mask pattern, the method including creating a test mask pattern by moving positions of plural edges in a given mask pattern according to a predetermined probability density distribution, the test mask pattern having dimension values which are different from dimension values of the given mask pattern, obtaining dimension values of a wafer pattern, which are measured by exposing a wafer with a test mask on which the test mask pattern is arranged, forming the wafer pattern on the wafer by the exposure, and measuring the dimension values of the wafer pattern on the wafer, obtaining a relationship between the dimension values of the wafer pattern and the dimension values of the test mask pattern, creating, by using the relationship, the mask pattern having dimension values by which a wafer pattern having predetermined dimension values is formed, and fabricating the photomask by using data of the created mask pattern.

Another aspect of the present invention is, for example, a method of manufacturing a semiconductor device by using a photomask fabricated by using data of a mask pattern, the method including creating a test mask pattern by moving positions of plural edges in a given mask pattern according to a predetermined probability density distribution, the test mask pattern having dimension values which are different from dimension values of the given mask pattern, obtaining dimension values of a wafer pattern, which are measured by exposing a wafer with a test mask on which the test mask pattern is arranged, forming the wafer pattern on the wafer by the exposure, and measuring the dimension values of the wafer pattern on the wafer, obtaining a relationship between the dimension values of the wafer pattern and the dimension values of the test mask pattern, creating, by using the relationship, the mask pattern having dimension values by which a wafer pattern having predetermined dimension values is formed, fabricating the photomask by using data of the created mask pattern, and manufacturing the semiconductor device by performing an exposure with the fabricated photomask.

### BRIEF DESCRIPTION OF THE DRAWINGS

FIG. 1 shows a planar view of a mask pattern;

FIG. 2 is a flowchart illustrating a test mask pattern creating process;

FIG. 3 is a graph showing calculated results of displacement amounts of edges;

FIG. 4 is a matrix scatter diagram showing a relationship between displacement amounts of edges;

FIG. 5 shows a planar view of a wafer pattern;

FIG. 6 is a conceptual diagram for explaining a neural network;

FIG. 7 is a flowchart illustrating a pattern data creating method;

FIG. 8 is a graph showing verified results of finish of a mask pattern;

FIG. 9 is a flowchart illustrating a photomask fabricating method;

FIGS. 10A to 11C show side sectional views illustrating a method of manufacturing a semiconductor device;

FIG. 12 shows a planar view of a mask pattern; and

FIG. 13 shows a relationship between mask dimensions and wafer dimensions in PLS regression.

### DESCRIPTION OF THE EMBODIMENTS

Embodiments of the present invention will be described with reference to the drawings.

### First Embodiment

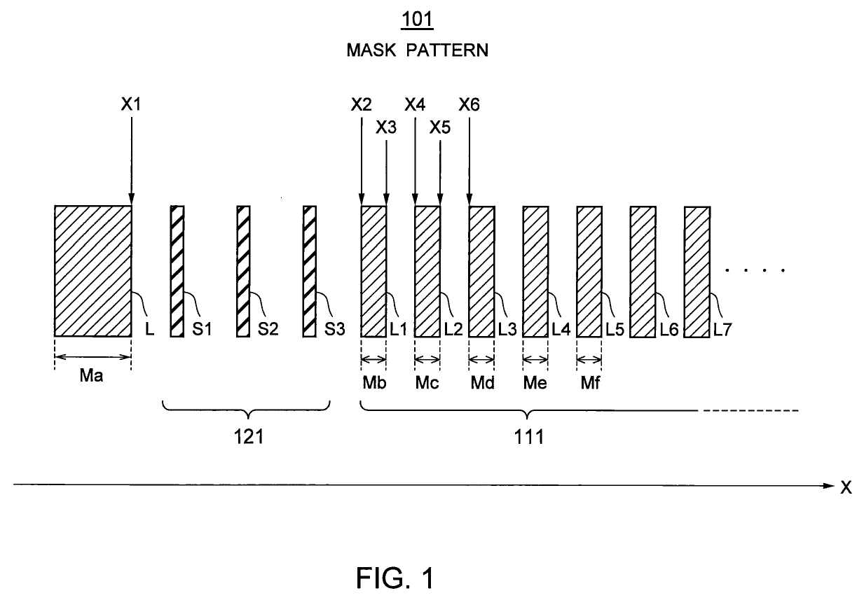

A pattern data creating method according to a first embodiment will be described below. In the pattern data creating method of the first embodiment, data of a mask pattern to be arranged on a photomask is created by correcting a given mask pattern. FIG. 1 shows a planar view illustrating an example of a pre-correction mask pattern.

A mask pattern 101 in FIG. 1 includes a thick line L, thin lines L1 to L7 forming an L/S (Line and Space) pattern 111, and lines S1 to S3 forming an SRAF (Sub Resolution Assist Feature) pattern 121.

The L/S pattern 111 is used to form an L/S pattern including lines having a width of 64 nm and spaces having a width of 64 nm on a wafer. The lines L1 to L7 are used to form the lines having the width of 64 nm on the wafer. On the other hand, the thick line L located outside the L/S pattern 111 is used to form a line having a width of 160 nm on the wafer.

In this embodiment, there is a possibility that the same pattern as the mask pattern is not formed on the wafer due to OPE. In other words, there is a possibility that the dimensions such as the width of 64 nm and the width of 160 nm are not realized. Therefore, in this embodiment, OPC of the mask pattern is performed such that the same pattern as the target is formed on the wafer. Further, the SRAF pattern is added to the mask pattern as follows.

The SRAF pattern 121 is used to enhance resolution. Although the SRAF pattern 121 is formed on the mask, the SRAF pattern 121 is not transferred onto the wafer. The lines S1 to S3 are fine lines that are not resolved.

In FIG. 1, the width of the line L is indicated by Ma, and the widths of the lines L1 to L5 are indicated by Mb to Mf respectively. Further, a right side edge of the line L is indicated by X1, a left side edge and a right side edge of the line L1 are indicated by X2 and X3, a left side edge and a right side edge of the line L2 are indicated by X4 and X5, and a left side edge of the line L3 is indicated by X6. Further, an axis which is extended in a direction perpendicular to these lines is indicated by “X”. It is assumed that a positive direction and a negative direction of the axis “X” are a right hand and a left hand, respectively.

In this embodiment, a test mask pattern is created by moving positions of plural edges in the mask pattern 101. The test mask pattern has dimension values which are different from dimension values of the mask pattern 101.

A dimension value of the mask pattern is a value with regard to a dimension of the mask pattern. Examples of the dimension value of the mask pattern include a mask dimension, a position of a mask edge, a distance between mask edges, a difference between a design value and a corrected value of the mask dimension, a difference between a design value and a corrected value of the position of the mask edge, a difference between a design value and a corrected value of the distance between the mask edges, and the like. The difference with regard to the mask dimension corresponds to an amount of change in mask dimension. Further, the difference with regard to the position of the mask edge corresponds to a displacement amount of the mask edge. Further, the difference with regard to the distance between the mask edges corresponds to an amount of change in distance between the mask edges. As described below, the dimension value of the mask pattern and a dimension value of a wafer pattern are used to correlate the dimension of the mask pattern and a dimension of the wafer pattern. Details of a method of using the dimension value of the mask pattern and the dimension value of the wafer pattern are described later. The dimension value of the wafer pattern is defined similarly to the dimension value of the mask pattern.

In this embodiment, it is assumed that mask dimensions of the mask pattern 101, i.e., the line widths Ma to Mf of the mask pattern 101 are used as the dimension values of the mask pattern 101. In this embodiment, the test mask pattern is created by moving the positions of the edges X1 to X6 in the mask pattern 101, whereby the test mask pattern differs from the mask pattern 101 in the line widths Ma to Mf.

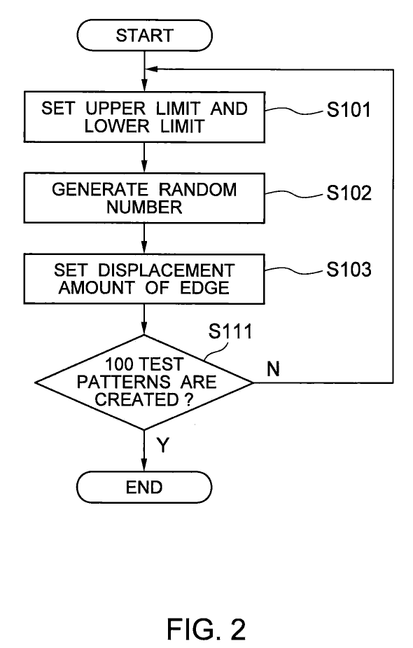

FIG. 2 is a flowchart illustrating a test mask pattern creating process. Hereinafter, the test mask pattern is simply referred to as test pattern.

First, upper limits (UL) and lower limits (LL) of displacement amounts of the edges X1 to X6 are set (S101). In this embodiment, the positions of the edges X1 to X6 are moved in the direction parallel to the axis “X”. Further, the right hand is set as the positive direction, and limitations when the edges are moved rightward are defined by the upper limits. Further, the left hand is set as the negative direction, and limitations when the edges are moved leftward are defined by the lower limits. In this embodiment, the upper limits and the lower limits are set for each edge. Therefore, each edge has its own upper limit and lower limit. Alternatively, the upper limit and the lower limit of the displacement amounts of the edges X1 to X6 may be commonly set for all the edges. In such a case, all the edges have the common upper limit and lower limit.

Next, a random number distributed in a numerical range of the upper limit to the lower limit is generated for each edge, according to a predetermined probability density distribution (S102). The upper limit and the lower limit become a maximum value and a minimum value of the random number, respectively. In this embodiment, it is assumed that the probability density distribution is a uniform distribution. Alternatively, the probability density distribution may be a normal distribution.

Next, the displacement amount of each edge is set at a value of the random number that is generated for each edge (S103). Thereby, one test pattern is created. In this way, the positions of the edges X1 to X6 in the mask pattern 101 are moved according to the predetermined probability density distribution, thereby creating the test pattern that differs from the mask pattern 101 in the line widths Ma to Mf.

In this embodiment, processes of S101 to S103 are repeated 100 times (S111). Thereby, 100 test patterns are created. When the line widths Ma to Mf of one test pattern is indicated by M1a to M1f while the line widths Ma to Mf of another test pattern is indicated by M2a to M2f, a relation of (M1a, M1b, . . . M1f)≠(M2a, Mb2, . . . M2f) is satisfied in this embodiment. In a case where N test patterns are created, the processes of S101 to S103 are repeated N times. N is an integer more than 1.

The 100 test patterns may include test patterns whose line widths Ma to Mf are accidentally equal to one another, and may include a test pattern whose line widths Ma to Mf are accidentally equal to those of the mask pattern 101. However, such situations are hardly generated when the random number has the sufficient number of figures, or when the number of the lines is sufficient. The line widths Ma to Mf of one test pattern may partially equal to the line widths Ma to Mf of another test pattern. Similarly, the line widths Ma to Mf of the test pattern may partially be equal to the line widths Ma to Mf of the mask pattern 101.

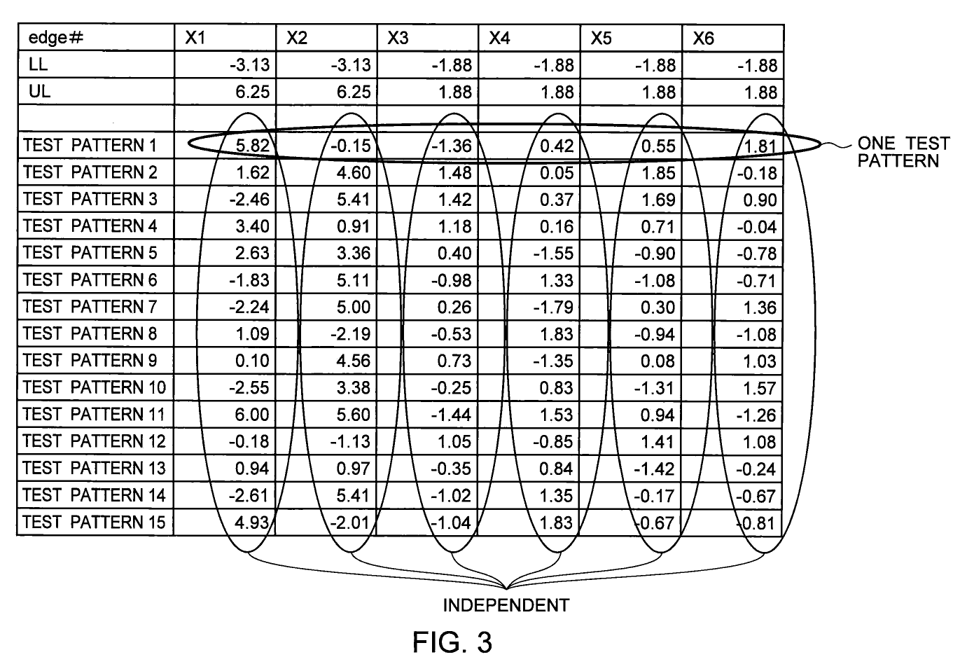

FIG. 3 is a graph showing calculated results of the displacement amounts of the edges X1 to X6. FIG. 3 illustrates the calculated results of the displacement amounts with regard to 15 test patterns. In FIG. 3, a positive value means a movement in the positive direction, and a negative value means a movement in the negative direction. In this embodiment, since the displacement amount of each edge is determined by the random number, the displacement amount of each edge is independent of the displacement amounts of other edges.

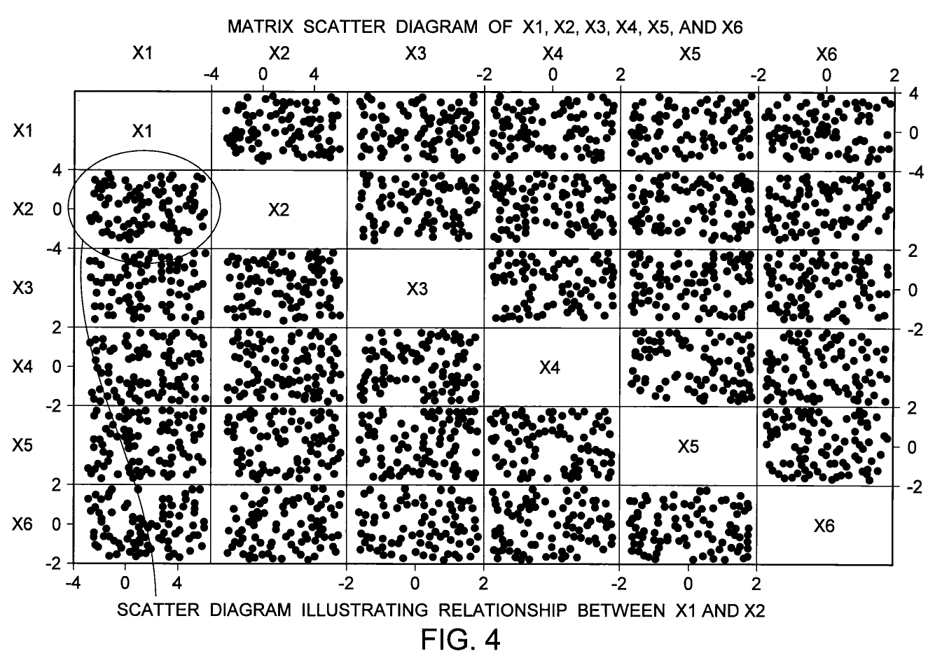

This is clearly illustrated in FIG. 4. FIG. 4 is a matrix scatter diagram showing a relationship between a displacement amount of an edge Xm and a displacement amount of an edge Xn (m and n=1 to 6). For example, a scatter diagram at an intersection of a column of X1 and a row of X2 shows the relationship between the displacement amount of the edge X1 and the displacement amount of the edge X2. As can be seen from the scatter diagram, the displacement amount of the edge X1 is independent of the displacement amount of the edge X2. The same holds true for other edges. As can be seen from FIG. 4, plots in FIG. 4 are substantially uniformly distributed. This is caused by generating the random number according to the uniform distribution.

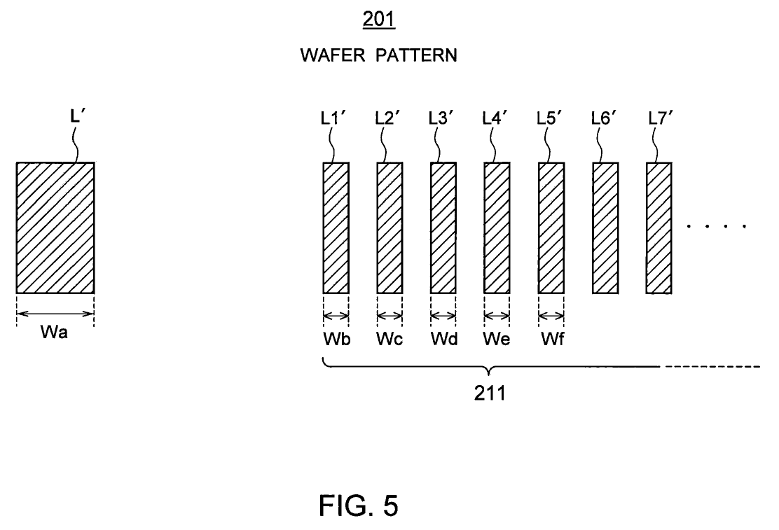

Subsequently, in this embodiment, one test mask in which the 100 test patterns are arranged is fabricated, and a wafer is exposed using the test mask. Thereby, a wafer pattern is formed on the wafer. For example, the exposure is performed with an ArF exposure apparatus. A resist to be exposed on the wafer may be a positive resist or a negative resist. FIG. 5 shows a planar view illustrating an example of the wafer pattern corresponding to one mask pattern.

A wafer pattern 201 in FIG. 5 includes a thick line L′, and thin lines L1′ to L7′ forming an L/S pattern 211. The thick line L′ corresponds to the thick line L in FIG. 1. As described above, a target value of the line width of the thick line L′ is 160 nm. The thin lines L1′ to L7′ correspond to the thin lines L1 to L7 in FIG. 1. As described above, target values of the line widths of the thin lines L1′ to L7′ are 64 nm.

In FIG. 5, the width of the line L′ is indicated by Wa, and the widths of the lines L1′ to L5′ are indicated by Wb to Wf respectively. The line width Wa of the line L′ corresponds to the line width Ma of the line L in FIG. 1. Similarly, the line widths Wb to Wf of the lines L1′ to L5′ correspond to the line widths Mb to Mf of the lines L1 to L5 in FIG. 1.

In this embodiment, 100 wafer patterns are formed according to the 100 mask patterns (test patterns). In this embodiment, the line widths Wa to Wf are measured for each of the 100 wafer patterns. The line widths Wa to Wf of the wafer patterns obtained by the measurement and the line widths Ma to Mf of the mask patterns are used to correlate the dimensions of the wafer patterns and the dimensions of the mask patterns. In this way, in this embodiment, the line widths Wa to Wf of the wafer patterns are used as the dimension values of the wafer patterns.

Subsequently, in this embodiment, a relationship between the dimension values of the wafer pattern and the dimension values of the mask pattern is obtained. In other words, the relationship between the line widths Wa to Wf of the wafer pattern and the line widths Ma to Mf of the mask pattern is obtained.

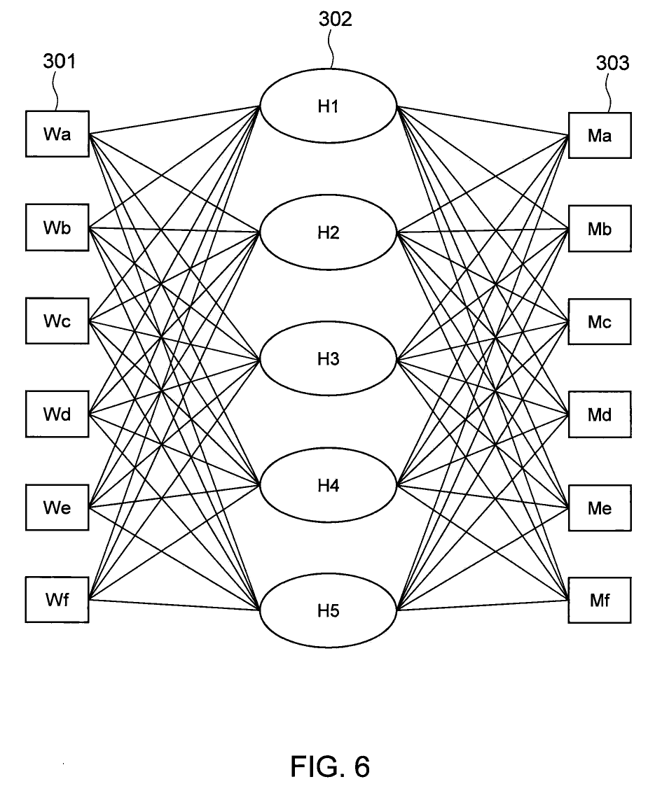

In this embodiment, the relationship between the dimension values of the wafer pattern and the dimension values of the mask pattern is obtained by analyzing the relationship between the line widths Wa to Wf and the line widths Ma to Mf by a neural network. The analysis by the neural network is performed using analysis software. FIG. 6 illustrates an example of the neural network.

FIG. 6 is a conceptual diagram for explaining the neural network. FIG. 6 illustrates a hierarchical neural network. FIG. 6 shows an input layer 301, an intermediate layer 302, and an output layer 303 of the neural network. In this embodiment, the line widths Wa to Wf of the wafer pattern are set in the input layer 301, and the line widths Ma to Mf of the mask pattern (test pattern) are set in the output layer 303. Then, the neural network learns the relationship between the line widths Wa to Wf and the line widths Ma to Mf. Thereby, the relationship between the line widths Wa to Wf and the line widths Ma to Mf is calculated.

The relationship obtained by the learning enables the line widths Ma to Mf to be calculated from the line widths Wa to Wf. In other words, the relationship obtained by the learning is a function in which the line widths Wa to Wf are inputs and the line width Ma to Mf are outputs. The line widths Wa to Wf of the 100 wafer patterns and the line widths Ma to Mf of the 100 mask patterns are used as 100 sets of initial values of the function. The line widths Wa to Wf of each wafer pattern are used in combination with the line widths Ma to Mf of the corresponding mask pattern.

Next, in this embodiment, the target values of the line width Wa to Wf of the wafer pattern are inputted into the input layer 301. Thereby, the output layer 303 outputs the line widths Ma to Mf of the mask pattern corresponding to the target values of the line width Wa to Wf of the wafer pattern. In this way, in this embodiment, the line widths Ma to Mf corresponding to the target values of the line width Wa to Wf are calculated by using the relationship. In this embodiment, the target value of the line width Wa is 160 nm, and the target values of the line widths Wb to Wf are 64 nm.

Next, in this embodiment, the mask pattern having the outputted line widths Ma to Mf is created. This provides the mask pattern having the line widths Ma to Mf by which the wafer pattern having the line widths Wa to Wf of the target values is to be formed. The target values of the line widths Wa to Wf of the wafer pattern is an example of predetermined dimension values of the wafer pattern in the present invention.

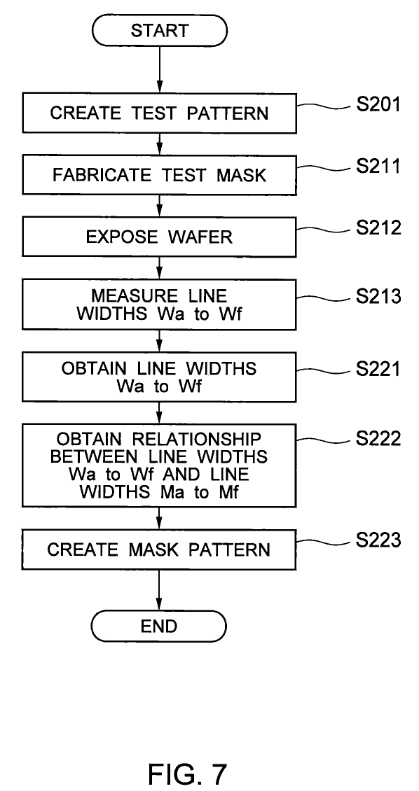

FIG. 7 is a flowchart illustrating a pattern data creating method.

First, a test pattern is created from a given mask pattern (S201). In this embodiment, 100 test patterns are created from one given mask pattern. These test patterns are created through the processes of S101 to S111 (see FIG. 2).

Next, a test mask on which the test pattern is arranged is fabricated (S211). In this embodiment, the 100 test patterns are arranged on one test mask. Next, a wafer pattern is formed on a wafer by exposing the wafer by using the test mask (S212). In this embodiment, 100 wafer patterns are formed on one wafer. Next, line widths Wa to Wf of the wafer pattern are measured (S213). In this embodiment, the line widths Wa to Wf of each of the 100 wafer patterns are measured.

Next, the line widths Wa to Wf of the wafer pattern measured by the measurement are obtained (S221). In this embodiment, the line widths Wa to Wf of each of the 100 wafer patterns are obtained. Next, a relationship between the line widths Wa to Wf of the wafer pattern and line widths Ma to Mf of a mask pattern are obtained (S222). In this embodiment, the relationship is calculated by using the line widths Wa to Wf of the 100 wafer patterns and the line widths Ma to Mf of the 100 test patterns. Next, the mask pattern having the line widths Ma to Mf by which the line widths Wa to Wf of the target values are formed are created by using the relationship (S223).

For example, the processes in S201 and S221 to S223 can be realized by a computer program. The computer program causes a computer to execute the processes in S201 and S221 to S223. Examples of the computer include a PC (Personal Computer) and a WS (Work Station). For example, the computer program is recorded in a computer readable recording medium. Examples of the recording medium include a semiconductor memory such as a flash memory and a magnetic memory such as a hard disk.

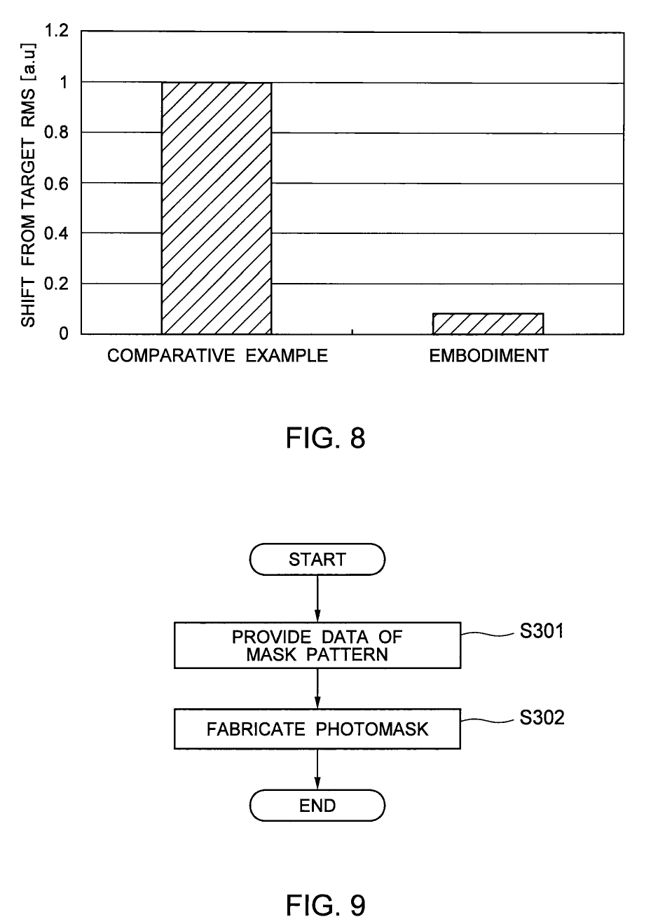

The inventors of the present invention created a mask pattern according to the method of this embodiment, fabricated a photomask on which the mask pattern is arranged, and performed an exposure with the photomask, to verify finish of the mask pattern. FIG. 8 is a graph showing verified results of the finish of the mask pattern.

FIG. 8 illustrates a shift between the target values and the measured values of the line widths of the wafer pattern, with regard to this embodiment and a comparative example. The shift shown in FIG. 8 is expressed by RSM (Root Mean Square) of the shifts with regard to the plural lines, and the shift shown in FIG. 8 is expressed in terms of a.u. (arbitrary unit).

The mask pattern of the comparative example was created as follows. First, the correction amount of each of the line widths Ma to Mf were set in eight ways. In this case, 8⁶ test patterns can be created in total, but only 100 test patterns were created in the comparative example. Next, the mask pattern was created through processes similar to those in S211 to S223.

The 100 test patterns are used in both of this embodiment and the comparative example. However, as can be seen from FIG. 8, the shift in this embodiment is smaller than that in the comparative example. This is attributed to the fact that the correction amounts in this embodiment scatter better than those in the comparative example when the test patterns are created.

As described above, in this embodiment, positions of plural edges in a given mask pattern are moved according to predetermined probability density distribution, thereby creating a test pattern that differs from the given mask pattern in line widths. In this embodiment, since the positions of the edges are moved according to the probability density distribution, the test pattern in which the positions of the edges are well scattered can be efficiently created. Therefore, the mask pattern can be accurately corrected with relatively few test patterns.

Further, in this embodiment, the probability density distribution is the uniform distribution. When the positions of the edges are moved according to the uniform distribution, the positions of the edges are scattered uniformly. Therefore, it is considered that the uniform distribution is preferred as the probability density distribution.

Further, in this embodiment, the relationship between the mask dimensions and the wafer dimensions is analyzed with the neural network. In general, it is considered that the relationship between the mask dimensions and the wafer dimensions includes a nonlinear relationship. Therefore, the neural network is effectively used to analyze the relationship between the mask dimensions and the wafer dimensions.

According to the neural network, an inverse calculation in which the mask dimensions are obtained from the wafer dimensions can be performed. Therefore, the analysis with the neural network is suitable to the pattern data creating method of this embodiment. In this embodiment, in order to perform the inverse calculation, the line widths of the wafer pattern are set in an input layer of the neural network, and the line widths of the mask pattern are set in its output layer.

In this embodiment, the relationship between the mask dimensions and the wafer dimensions may be analyzed by a technique except for the neural network. An example of the technique is described in a second embodiment.

The description is made again with reference to FIG. 1.

The L/S pattern 111 in FIG. 1 is a periodic pattern having the thin lines L1 to L7 that are periodically arranged. On the other hand, the thick line L is an aperiodic pattern.

In this embodiment, the test pattern is created by moving the edges X1 to X6, i.e., the edges located in a vicinity of the boundary between the periodic pattern and the aperiodic pattern. This is because the patterns located in a vicinity of a region where periodicity is disturbed are easily influenced by OPE. Therefore, in this embodiment, OPC is performed effectively by correcting the positions of the edges X1 to X6.

Similarly, the line widths Ma to Mf to be used as the dimension values are selected from the lines located in the vicinity of the boundary between the periodic pattern and the aperiodic pattern.

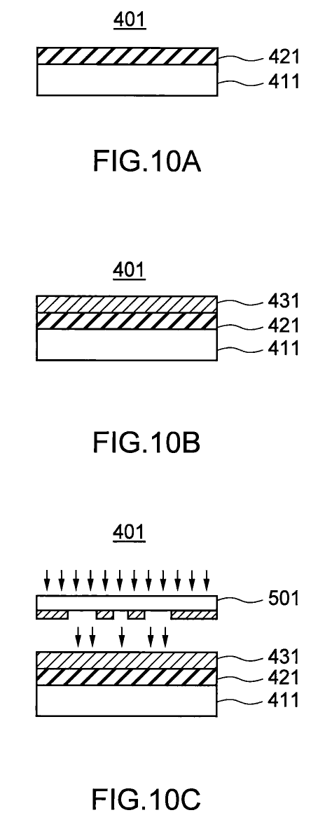

As described above, in this embodiment, the given mask pattern is corrected so as to create the data of the mask pattern to be arranged on a photomask. In fabricating the photomask, as illustrated in FIG. 9, the data of the mask pattern obtained by the correction is provided (S301), and the photomask is fabricated by using the data (S302). Thereby, the photomask which can form a wafer pattern close to the target is fabricated. FIG. 9 is a flowchart illustrating a photomask fabricating method for fabricating the photomask.

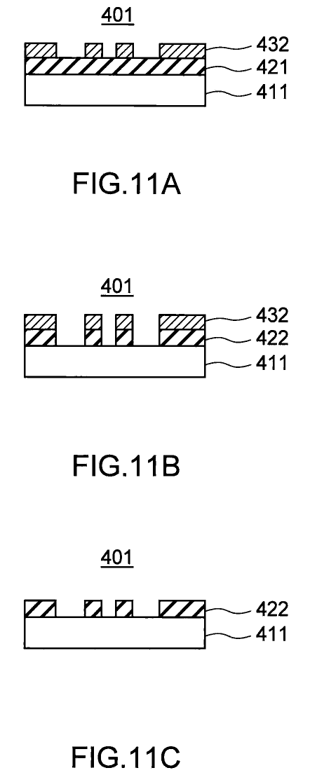

For example, the photomask can be used in a method of manufacturing a semiconductor device. FIGS. 10A to 11C show side sectional views illustrating an example of a method of manufacturing a semiconductor device 401. In FIGS. 10A to 11C, an interconnect layer is described as an example of a layer to be etched.

First, as shown in FIG. 10A, an interconnect layer 421, which is a layer to be etched, is formed on a substrate (wafer) 411. For example, the substrate 411 is a semiconductor substrate such as a silicon substrate. For example, the interconnect layer 421 is a metal interconnect layer such as an aluminum interconnect layer. The interconnect layer 421 may be directly formed on the substrate 411, or may be formed on the substrate 411 via another layer.

Next, as shown in FIG. 10B, a resist layer 431 is formed on the interconnect layer 421. The resist layer 431 may be a positive resist layer or a negative resist layer.

Next, as shown in FIG. 10C, a wafer is exposed by using a photomask 501. More specifically, the resist layer 431 on the wafer is exposed. In the exposure, the photomask 501 which is fabricated in the processes of S301 and S302 (see FIG. 9) is provided, and the resist layer 431 is exposed by using the photomask 501. According to the exposure, the mask pattern on the photomask 501 is transferred to the resist layer 431.

Next, as shown in FIG. 11A, the resist layer 431 is developed to form a resist pattern (wafer pattern) 432 on the interconnect layer 421.

Next, as shown in FIG. 11B, the interconnect layer 421 is etched by using the resist pattern 432 as a mask. Thereby, an interconnect pattern 422 is formed on the substrate 411.

Next, as shown in FIG. 11C, the resist pattern 432 is removed. In this way, the semiconductor device 401 is manufactured.

The layer to be etched may be a layer except for the interconnect layer. Examples of the layer to be etched include a gate electrode layer, a hard mask layer, and the like. Further, the layer to be etched may be the substrate 401.

A second embodiment will be described below. The second embodiment is a modification of the first embodiment. Therefore, the following description on the second embodiment will be focused on the points different from the first embodiment.

### Second Embodiment

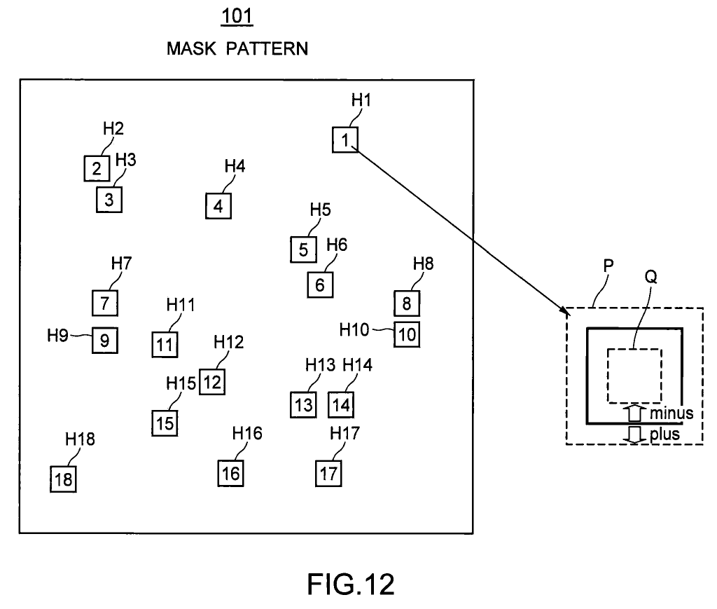

A pattern data creating method of a second embodiment will be described below. In the pattern data creating method of the second embodiment, data of a mask pattern to be arranged on a photomask is created by correcting a given mask pattern. FIG. 12 shows a planar view illustrating an example of a pre-correction mask pattern.

A mask pattern 101 in FIG. 12 is a hole pattern including 18 holes H1 to H18. The holes H1 to H18 are randomly dispersed in a region shown in FIG. 12. Each of the holes H1 to H18 has a square shape. Further, the holes H1 to H18 have the same hole size (i.e., have the same side length).

In the first embodiment, the positions of the edges X1 to X6 in the mask pattern 101 are moved to create a test pattern that differs from the mask pattern 101 in the line widths Ma to Mf.

On the other hand, in the second embodiment, the edges to be moved are four sides of each hole. In the second embodiment, positions of the four sides of each hole are moved to create a test pattern that differs from the mask pattern 101 in hole sizes of the holes H1 to H18.

In moving the four sides of one hole, the four sides are moved by the same displacement amount. Therefore, when the four sides of a hole are moved, the shape of the hole is magnified to a larger square or reduced to a smaller square. In this way, in this embodiment, the positions of the four sides of the holes H1 to H18 are moved such that the holes H1 to H18 are magnified or reduced, thereby creating the test pattern. FIG. 12 shows an example of the magnified square, which is indicated by “P”, and an example of the reduced square, which is indicated by “Q”.

A test pattern creating process in the second embodiment can be performed similarly to that in the first embodiment. In other words, in the second embodiment, the test pattern can be created through the processes in FIG. 2. However, the displacement amounts of the edges X1 to X6 are replaced with change amounts of the hole sizes of the holes H1 to H18. Further, the upper limit of the magnification of the hole sizes is defined by the value of UL, and the lower limit of the reduction of the hole sizes is defined by the value of LL.

Further, in the second embodiment, processes of creating a desired mask pattern from the test pattern can be also performed similarly to those in the first embodiment. In other words, the desired mask pattern can be created through the processes of S211 to S223 in FIG. 7.

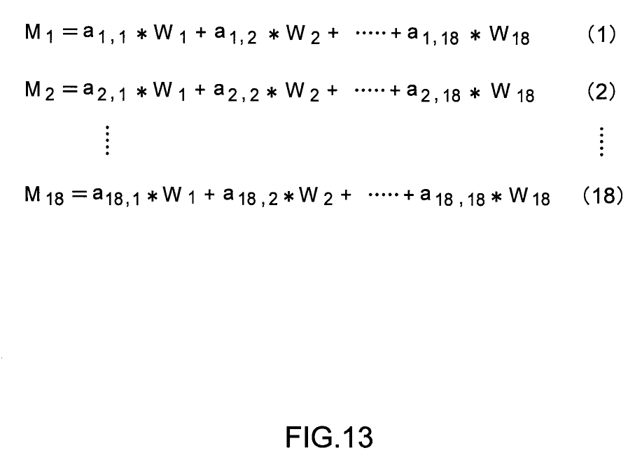

However, in this embodiment, the relationship between the mask dimensions and the wafer dimensions is analyzed by PLS (Partial Least Square) regression. The PLS regression corresponds to linear regression, and is well known as one of multivariable analysis techniques. In the PLS regression, the wafer dimensions are set as factors (inputs) while the mask dimensions are set as responses (outputs), whereby the relationship as shown in FIG. 13 is obtained. FIG. 13 shows the relationship between the mask dimensions and the wafer dimensions in the PLS regression.

In FIG. 13, a_{1,1} to a_{18,18} denote regression coefficients. Further, W1 to W18 denote hole sizes of the holes H1 to H18 in the wafer pattern, respectively. Further, M₁ to M₁₈ denotes hole sizes of the holes H1 to H18 in the mask pattern (test pattern), respectively. Equations (1) to (18) are used to calculate M₁ to M₁₈. In this embodiment, the values of M₁ to M₁₈ in a desired mask pattern can be calculated by substituting the target values into W₁ to W₁₈ of the equations (1) to (18). Alternatively, the relationship between the mask dimensions and the wafer dimensions may be analyzed by nonlinear regression such as support vector regression.

In this way, the desired mask pattern is created. The process of fabricating a photomask from the mask pattern can be performed as illustrated in FIG. 9. Further, the process of manufacturing a semiconductor device by using the photomask can be performed as illustrated in FIGS. 10A to 11C.

As described above, the embodiments of the present invention can provide a pattern data creating method which can improve, in creating mask pattern data used for correcting a mask pattern, the efficiency and accuracy of the correction.

Although specific examples of aspects of the present invention have been described by the first and second embodiments, the present invention is not limited to these embodiments.

What is claimed is:

1. A pattern data creating method for creating data of a mask pattern to be arranged on a photomask, the method comprising:
creating a test mask pattern by moving positions of plural edges in a given mask pattern according to a predetermined probability density distribution, the test mask pattern having dimension values which are different from dimension values of the given mask pattern;
obtaining dimension values of a wafer pattern, which are measured by exposing a wafer with a test mask on which the test mask pattern is arranged, forming the wafer pattern on the wafer by the exposure, and measuring the dimension values of the wafer pattern on the wafer;
obtaining a relationship between the dimension values of the wafer pattern and the dimension values of the test mask pattern; and
creating, by using the relationship, the mask pattern having dimension values by which a wafer pattern having predetermined dimension values is formed.

2. The method according to claim 1, wherein
the predetermined probability density distribution is a uniform distribution.

3. The method according to claim 1, wherein
the predetermined probability density distribution is a normal distribution.

4. The method according to claim 1, wherein
the relationship is obtained by analyzing the relationship by a neural network, linear regression, or nonlinear regression.

5. The method according to claim 4, wherein
the linear regression is PLS (Partial Least Square) regression.

6. The method according to claim 4, wherein
the nonlinear regression is support vector regression.

7. The method according to claim 4, wherein
in analyzing the relationship by the neural network, the dimension values of the wafer pattern are set in an input layer, and the dimension values of the test mask pattern are set in an output layer.

8. The method according to claim 5, wherein
in analyzing the relationship by the PLS regression, the dimension values of the wafer pattern are set as factors, and the dimension values of the test mask pattern are set as responses.

9. The method according to claim 1, wherein
the positions of the plural edges in the given mask pattern are moved within a range of an upper limit to a lower limit.

10. The method according to claim 9, wherein
each of the plural edges is moved within the range of the upper limit to the lower limit which are set for each edge.

11. The method according to claim 9, wherein
a random number distributed in a numerical range of the upper limit to the lower limit is generated according to the predetermined probability density distribution, and
a displacement amount of each of the plural edges is set at a value of the random number generated for each edge.

12. The method according to claim 1, wherein
the test mask pattern is created by moving a position of an edge located in a vicinity of a boundary between a periodic pattern portion of the given mask pattern and an aperiodic pattern portion of the given mask pattern.

13. The method according to claim 1, wherein
the given mask pattern is an L/S (Line and Space) pattern including plural lines.

14. The method according to claim 1, wherein
the given mask pattern is a hole pattern including plural holes.

15. The method according to claim 14, wherein
the positions of the plural edges are moved to magnify or reduce shapes of the holes.

16. The method according to claim 15, wherein
the shapes of the holes are magnified or reduced within a range of an upper limit to a lower limit.

17. The method according to claim 1, wherein
the method is performed by a computer executing a computer program for performing the method.

18. A photomask fabricating method for fabricating a photomask by using data of a mask pattern, the method comprising:
creating a test mask pattern by moving positions of plural edges in a given mask pattern according to a predetermined probability density distribution, the test mask pattern having dimension values which are different from dimension values of the given mask pattern;
obtaining dimension values of a wafer pattern, which are measured by exposing a wafer with a test mask on which the test mask pattern is arranged, forming the wafer pattern on the wafer by the exposure, and measuring the dimension values of the wafer pattern on the wafer;
obtaining a relationship between the dimension values of the wafer pattern and the dimension values of the test mask pattern;
creating, by using the relationship, the mask pattern having dimension values by which a wafer pattern having predetermined dimension values is formed; and
fabricating the photomask by using data of the created mask pattern.

19. A method of manufacturing a semiconductor device by using a photomask fabricated by using data of a mask pattern, the method comprising:
creating a test mask pattern by moving positions of plural edges in a given mask pattern according to a predetermined probability density distribution, the test mask pattern having dimension values which are different from dimension values of the given mask pattern;
obtaining dimension values of a wafer pattern, which are measured by exposing a wafer with a test mask on which the test mask pattern is arranged, forming the wafer pattern on the wafer by the exposure, and measuring the dimension values of the wafer pattern on the wafer;
obtaining a relationship between the dimension values of the wafer pattern and the dimension values of the test mask pattern;
creating, by using the relationship, the mask pattern having dimension values by which a wafer pattern having predetermined dimension values is formed;
fabricating the photomask by using data of the created mask pattern; and
manufacturing the semiconductor device by performing an exposure with the fabricated photomask.
